(19) United States
(12) Patent Application Publication
(10) Pub. No.: US 2019/0112865 A1
(43) Pub. Date: Apr. 18, 2019

(54) DOOR APPARATUS FOR CHAMBER

(71) Applicant: In Jae CHANG, Yongin-si (KR)

(72) Inventor: In Jae CHANG, Yongin-si (KR)

(21) Appl. No.: 15/955,742

(22) Filed: Apr. 18, 2018

(30) Foreign Application Priority Data
Oct. 12, 2017 (KR) 10-2017-0132320

(51) Int. Cl. E06B 3/46; E06B 5/12; E05F 15/697; G01R 31/28

(52) U.S. Cl. CPC E06B 3/46; E06B 5/12; G01R 31/2619; G01R 31/2862; E05F 15/697

(57) ABSTRACT

The present invention relates to a door apparatus for a chamber, and according to one aspect of the present invention, there is provided a door apparatus for a chamber comprising: a pair of guide rails provided at an inlet side of the chamber; a support frame movably disposed along the pair of guide rails; a door mounted to the support frame to be positioned between the inlet side of the chamber and the support frame; a first drive part provided to move the support frame along the pair of guide rails; and a second drive part provided to move the door relative to the support frame for pressing the door to the inlet or detaching it from the inlet with the door being positioned in front of the inlet by the first drive part.

### RELATED APPLICATION

This application claims the benefit of priority of Korean Patent Application No. 10-2017-0132320 filed Oct. 12, 2017, the contents of which are incorporated herein by reference in their entirety.

### FIELD AND BACKGROUND OF THE INVENTION

The present invention relates to a door apparatus for a chamber, and in particular, relates to a door apparatus for a chamber for a thermal shock test of semiconductors or various electronic equipments.

Semiconductor processes are mostly carried out in a sealed chamber, where an inlet of the chamber is opened and closed through a door apparatus.

For example, a burn-in test chamber used in semiconductor processes is a device that tests reliability of a packaged semiconductor device for thermal shock (stress) when powering and operating the semiconductor device.

Such a test chamber must be closed at the inlet of the chamber so that it is not affected by the external environment during the processes.

Therefore, it is required to develop a door apparatus which is capable of ensuring sufficient sealing force and has stability of opening and closing operation.

### SUMMARY OF THE INVENTION

It is a problem to be solved by the present invention to provide a door apparatus for a chamber which is stable in opening and closing operation and has excellent sealing force.

To solve the above-described problem, according to one aspect of the present invention, there is provided a door apparatus for a chamber comprising: a pair of guide rails provided at an inlet side of the chamber; a support frame movably disposed along the pair of guide rails; a door mounted to the support frame to be positioned between the inlet side of the chamber and the support frame; a first drive part provided to move the support frame along the pair of guide rails; and a second drive part provided to move the door relative to the support frame for pressing the door to the inlet or detaching it from the inlet with the door being positioned in front of the inlet by the first drive part.

As described above, the door apparatus for a chamber according to one embodiment of the present invention has the following effects.

The apparatus has a structure that the door is pressed from the outside of the chamber to the inlet side of the chamber, which has excellent sealing force and allows stable opening and closing operation by separately performing moving operation to opening and closing positions and pressing/detaching operation through the individual drive parts.

### BRIEF DESCRIPTION OF THE SEVERAL VIEWS OF THE DRAWINGS

FIG. 1 is a main part perspective view of a door apparatus for a chamber related to one embodiment of the present invention.

FIG. 2 is a front view of the chamber.

FIG. 3 is a perspective view showing some components of the door apparatus for a chamber shown in FIG. 1.

FIG. 4 is an upper side elevational view of the door apparatus for a chamber shown in FIG. 1.

FIG. 5 is a lower side elevational view of the door apparatus for a chamber shown in FIG. 1.

### DESCRIPTION OF SPECIFIC EMBODIMENTS OF THE INVENTION

Hereinafter, a door apparatus for a chamber according to one embodiment of the present invention will be described in detail with reference to the accompanying drawings.

In addition, the same or similar reference numerals are given to the same or corresponding components regardless of reference numerals, of which redundant explanations will be omitted, and for convenience of explanation, the size and shape of each constituent member as shown may be exaggerated or reduced.

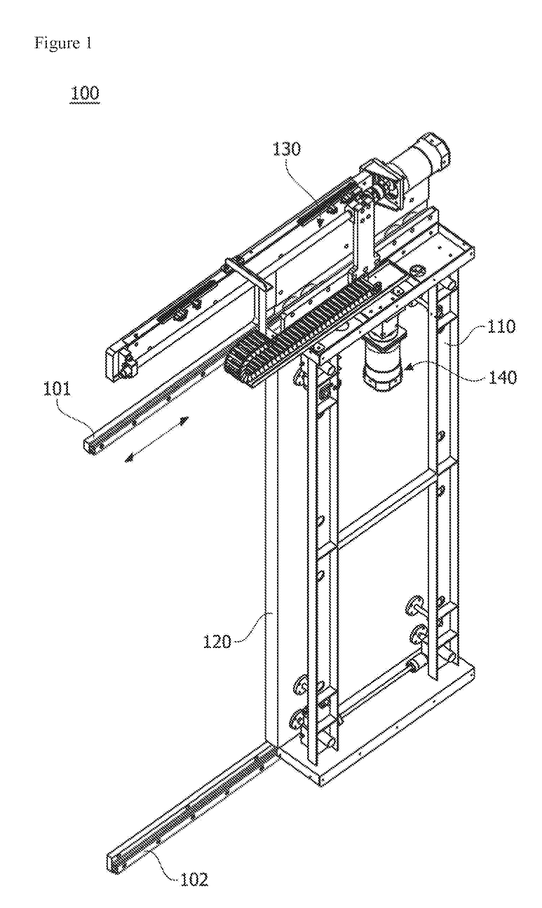

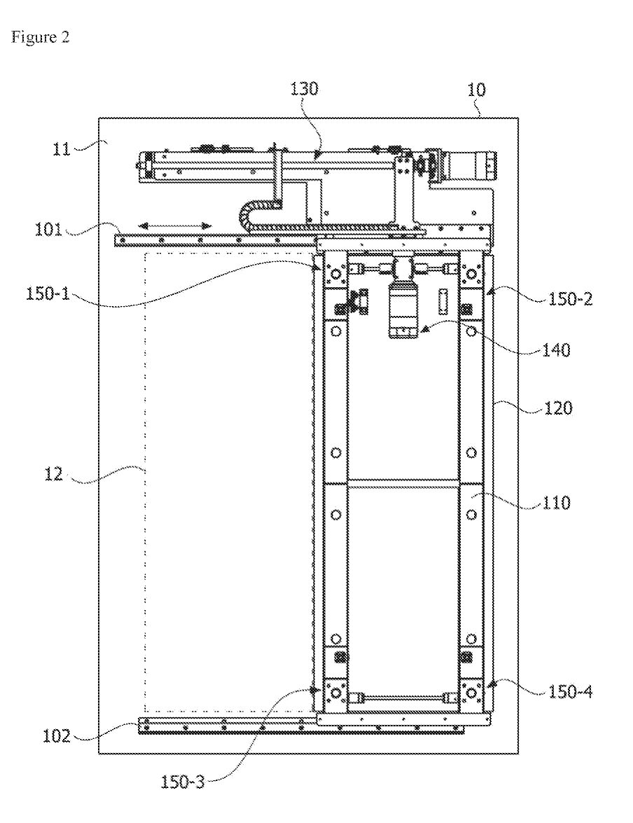

FIG. 1 is a main part perspective view of a door apparatus for a chamber according to one embodiment of the present invention, and FIG. 2 is a front view of the chamber.

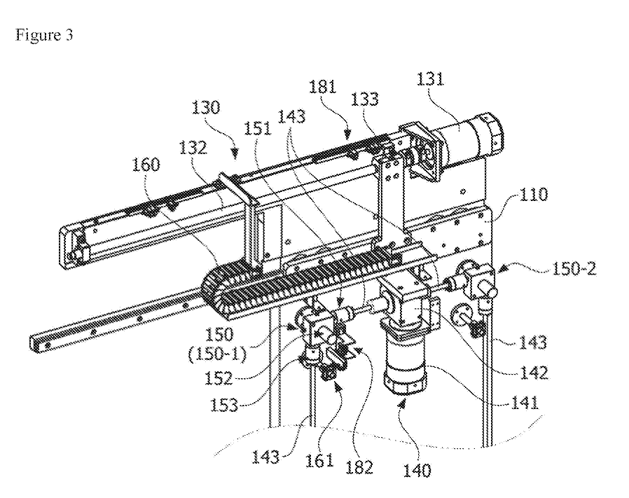

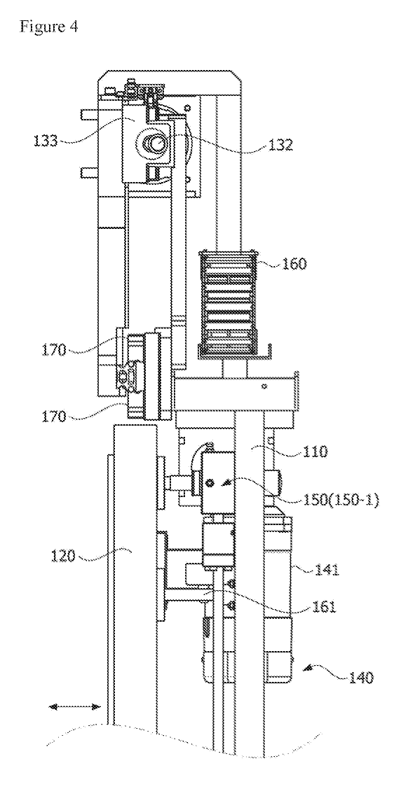

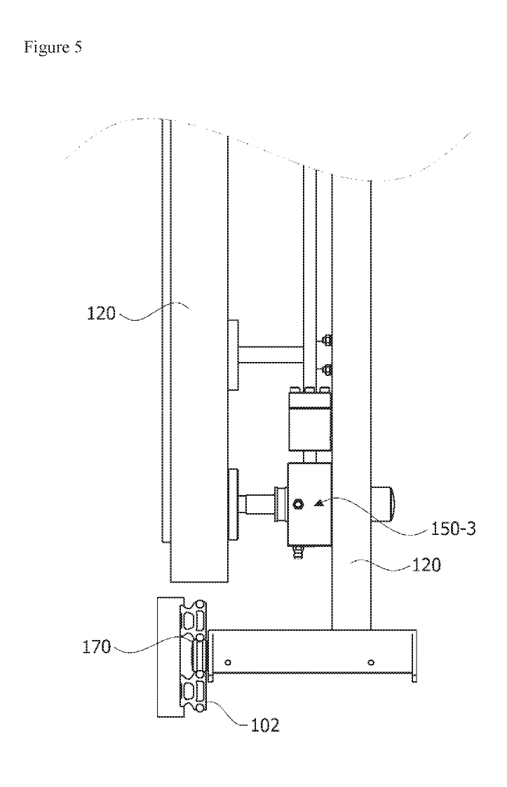

Also, FIG. 3 is a perspective view showing some components of the door apparatus for a chamber shown in FIG. 1, FIG. 4 is an upper side elevational view of the door apparatus for a chamber shown in FIG. 1, and FIG. 5 is a lower side elevational view of the door apparatus for a chamber shown in FIG. 1.

In this document, the chamber (10) may comprise a test chamber for thermal shock test of semiconductors and various electronic equipments.

For example, the chamber may be a burn-in test chamber. The burn-in test chamber is a chamber for testing a semiconductor device loaded on a test board using a tester substrate. The burn-in test chamber may be equipped with a board chamber (or burn-in chamber) accommodating semiconductor devices and a tester chamber in which a tester substrate for applying a test signal to the semiconductor devices accommodated in the board chamber and then reading a feedback result signal is accommodated.

Also, the chamber (10) comprises a door apparatus (100) for a chamber. The chamber (10) has an inlet (12) through which a test substrate or the like enters the inside or a test substrate or the like accommodated therein is taken out to the outside. In addition, the inlet (12) is provided on the front surface of the chamber (10).

The door apparatus (100) for a chamber comprises a pair of guide rails (101, 102), a support frame (110), a door (120), a first drive part (130) and a second drive part (140).

Specifically, the door apparatus (100) for a chamber comprises a pair of guide rails (101, 102) provided at the inlet (12) side of the chamber (10).

At this time, the pair of guide rails (101, 102) comprises an upper guide rail (101) provided in an inlet side upper region of the front surface (11) of the chamber (10) and a lower guide rail (102) provided in an inlet side lower region of the front surface (11) of the chamber (10).

The upper and lower guide rails (101, 102) are extended along the width direction of the chamber (10) (the left and right directions of the front surface (11) in FIG. 2), respectively. Also, each of the upper and lower guide rails (101, 102) may have a length twice or more of the width of the door (120) for sealing the inlet (12).

The door apparatus (100) for a chamber comprises a support frame (110) movably disposed along the pair of guide rails. The support frame (110) may be formed of a metal material and/or a resin material so as to have a predetermined rigidity. For example, the support frame (110) may have a frame shape that approximately overlaps with the edge of the door (120), without being limited thereto.

Referring to FIGS. 4 and 5, the support frame (120) is provided with a plurality of rollers (170), each of which can run along the guide rail.

In particular, referring to FIG. 4, in the upper guide rail (101) side, a plurality of rollers (170), which are disposed on the upper/lower parts of the upper guide rail (101) so that they can each run, may be provided on the support frame (110).

Furthermore, referring to FIG. 5, in the lower guide rail (102) side, a roller (170), which is mounted on the lower guide rail (102) so that it can run, may be provided on the support frame (110).

Also, the door apparatus (100) for a chamber comprises a door (120) mounted on the support frame (120) so as to be positioned between the inlet (12) side of the chamber (10) and the support frame (110). The door (120) performs a function to seal the inlet (12) of the chamber (10). The size of the door (120) may be equal to or greater than the size of the inlet (12).

The door (120) is mounted to the support frame (110) to either advance toward the inlet (12) or retract from the inlet (12) so that it can be pressed to the inlet (12) or detached from the inlet (12).

Furthermore, the door apparatus (100) for a chamber comprises a first drive part (130) provided to move the support frame (120) along the pair of guide rails (101, 102).

The first drive part (130) may be installed on the front surface of the chamber (10) in the inlet side upper region. In addition, the first drive part (130) may comprise a motor and a ball screw.

For example, referring to FIG. 3, the first drive part (130) may comprise a first drive motor (131) being rotated normally or reversely, a ball screw shaft (132) being connected to a rotation axis of the first drive motor (131), and a ball screw nut (133) reciprocating in the longitudinal direction of the ball screw shaft (132) depending on rotation of the ball screw shaft (132).

The ball screw nut (133) is mounted on the support frame (110). Accordingly, if the first drive motor (131) rotates in a predetermined direction (normal rotation or reverse rotation), the ball screw shaft (132) rotates and the support frame (110) fixed to the ball screw nut (133) moves along the pair of guide rails (101, 102). For example, upon normal rotation of the first drive motor (131), the support frame (110) may move to the closed position of the inlet (12), and conversely, upon reverse rotation of the first drive motor (131), the support frame (110) may move to the opened position of the inlet (12) (the position of the support frame in FIG. 2). Also, depending on the left and right slide movement of the support frame (110) along the pair of guide rails (101, 102), the door (120) may move to the closed position of the inlet (12) and the opened position of the inlet (12).

As in FIG. 2, the door (120) and the inlet (12) overlap with each other at the closed position of the inlet (12), and the door (120) and the inlet (12) do not overlap at the open position of the inlet (12) and are positioned side by side in the left and right direction, based on the front surface (11) of the chamber (10).

Also, the door apparatus (100) for a chamber comprises a second drive part (140) provided such that the door (120) is moved forward/backward with respect to the support frame (110) to press the door (120) to the inlet (12) or detach it from the inlet (12) in a state (closed position of the inlet) where the door (120) is positioned in front of the inlet (120) by the first drive part (130).

The second drive part (140) comprises a second drive motor (141) being rotated normally or reversely, and a shaft (143) for transmitting rotational force generated by the second drive motor (141). At this time, a plurality of the shafts (143) may be provided.

Furthermore, the second drive part (140) may comprise a gear box (142) for transmitting rotational force generated by the second drive motor (141) to two different output ports. Referring to FIG. 3, the gear box (142) may be configured such that it is connected to a rotation axis of the second drive motor (141) and two shafts (143) are each connected thereto.

In this structure, if the second drive motor (141) rotates, two shafts (143) connected to the gear box (142) may be each rotated by the gear box (142). Through this structure, the second drive motor (141) may transmit the rotational force to first and second cylinder gear boxes (150-1, 150-2) to be described below, respectively.

In addition, the second drive part (140) comprises a cylinder gear box (150) for connecting the door (120) and the support plate (110), and moving the door (120) forward to the inlet (12) side and backward from the inlet (12) side, with respect to the support frame (120), by using the rotational force of the shaft (143). A plurality of the cylinder gear boxes (150) may be provided so that they may be mounted in a plurality of regions of the door (120), respectively. The plurality of cylinder gear boxes (150) may have the same structure to perform the same function.

The cylinder gear box (150) may comprise a first rotation axis, a cylinder part and a second rotation axis. Referring to FIG. 3, the cylinder gear box (150, for example, 150-1) may comprise a first rotation axis (151) to which rotational power is input, a cylinder part (152) moving forward/backward by the rotational power of the first rotation axis (151) and a second rotation axis (153) protruding in a direction different from the first rotation axis (151) and rotating by the rotational power of the first rotation axis (151). Furthermore, a coupler may be mounted on each rotation axis.

For example, the cylinder part (152) of the cylinder gear box (150) may be fixed to the support frame (110), and a mounting flange part of the cylinder gear box (150) may be fixed to the door (120).

Besides, the cylinder gear box (150) may comprise first to fourth cylinder gear boxes (150-1, 150-2, 150-3, 150-4) mounted on the upper region left/right sides and the lower region left/right sides of the door (120), respectively.

At this time, as described above, the first and second cylinder gear boxes (150-1, 150-2) disposed at the upper region left/right sides of the door (120) may be each connected to the second drive motor (141) via the shaft (143) and the gear box (142).

Also, the third cylinder gear box (150-3) disposed on the lower region left side of the door (120) may be connected to the first cylinder gear box (150-1) via the shaft (143). Furthermore, the fourth cylinder gear box (150-4) disposed on the lower region right side of the door (120) may be connected to the second cylinder gear box (150-2) via the shaft (143). In addition, the third and fourth cylinder gear boxes (150-3, 150-4) may be connected via the shaft.

At this time, if the second drive motor (141) rotates in a predetermined direction (normal rotation/reverse rotation), the rotational force of the second drive motor (141) is transmitted to each of the cylinder gear boxes (150-1, 150-2, 150-3, 150-4), and the first to fourth cylinder gear boxes (150-1, 150-2, 150-3, 150-4) are provided to simultaneously move (forward or backward) the door.

Furthermore, one or more ball bushes (161) may be further provided between the support frame and the door.

In the structure as above, the door (120) and the support frame (120) move together to the closed position of the inlet (12) by the operation of the first drive part (130), and then the door (120) moves forward to the inlet (12) side by the operation of the second drive part (140) to press the inlet (12).

Alternatively, the door (120) retracts from the inlet (12) by the operation of the second drive part (140) to detach from the inlet (12), and the door (120) and the support frame (120) move together to the opened position of the inlet (12) by the operation of the first drive part (130).

On the other hand, the unexplained reference numeral 160 denotes a cable tray, 181 denotes a first limit switch for sensing the position of the support frame, and 182 denotes a second limit switch for sensing the position of the door.

The preferred embodiments of the present invention as described above are disclosed for exemplary purpose, where those skilled in the art having ordinary knowledge for the present invention can make various corrections, modifications and additions within idea and scope of the present invention, and such a correction, modification and addition should be considered as falling within the scope of the following claims.

### EXPLANATION OF REFERENCE NUMERALS

10: chamber
12: inlet
100: door apparatus for chamber
101, 102: guide rail
110: support frame
120: door
130: first drive part
140: second drive part
150: cylinder gear box
160: cable tray
170: roller
181, 182: limit switch

What is claimed is:

1. A door apparatus for a chamber comprising:
a pair of guide rails provided at an inlet side of the chamber;
a support frame movably disposed along the pair of guide rails;
a door mounted to the support frame to be positioned between the inlet side of the chamber and the support frame;
a first drive part provided to move the support frame along the pair of guide rails; and
a second drive part provided to move the door relative to the support frame for pressing the door to the inlet or detaching it from the inlet with the door being positioned in front of the inlet by the first drive part.

2. The door apparatus for a chamber according to claim 1, wherein the second drive part comprises:
a second drive motor being rotated normally or reversely;
a shaft for transmitting rotational force generated by the second drive motor; and
a cylinder gear box for connecting the door and the support plate, and moving the door forward to the inlet side and backward from the inlet side, with respect to the support frame, by using the rotational force of the shaft.

3. The door apparatus for a chamber according to claim 2, wherein the cylinder gear box comprises:
a first rotation axis to which rotational power is input;
a cylinder part moving forward/backward by the rotational power of the first rotation axis; and
a second rotation axis protruding in a direction different from the first rotation axis and rotating by the rotational power of the first rotation axis.

4. The door apparatus for a chamber according to claim 3, wherein
the cylinder gear box comprises first to fourth cylinder gear boxes mounted on the upper region left/right sides and the lower region left/right sides of the door, respectively,
the first and second cylinder gear boxes disposed on the upper region left/right sides are each connected to the second drive motor via the shaft,
the third cylinder gear box disposed on the lower region left side is connected to the first cylinder gear box via the shaft, and the fourth cylinder gear box disposed on the lower region right side is connected to the second cylinder gear box via the shaft,
the third and fourth cylinder gear boxes are connected via the shaft, and
the first to fourth cylinder gear boxes are provided so as to simultaneously move the door depending on the rotation of the second drive motor.

5. The door apparatus for a chamber according to claim 1, wherein the first drive part comprises:
a first drive motor being rotated normally or reversely;
a ball screw shaft connected to the rotation axis of the first drive motor; and
a ball screw nut reciprocating in the longitudinal direction of the ball screw shaft depending on rotation of the ball screw shaft, and
the ball screw nut is mounted to the support frame.

6. The door apparatus for a chamber according to claim 1, wherein
the support frame is provided with a plurality of rollers, each of which can run along the guide rail.

7. The door apparatus for a chamber according to claim 1, wherein
a ball bush is provided between the support frame and the door.
